(19) United States
(12) Patent Application Publication
(10) Pub. No.: US 2008/0153240 A1
(43) Pub. Date: Jun. 26, 2008

(54) Method for Fabricating Semiconductor Device

(75) Inventors: Tsing Chow WANG, Shanghai (CN); Meng ZHAO, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: Semiconductor Manufacturing International (Shanghai) Corporation, Shanghai (CN)

(21) Appl. No.: 11/867,645

(22) Filed: Oct. 4, 2007

(30) Foreign Application Priority Data
Dec. 22, 2006 (CN) 200610147805.4

(51) Int. Cl. H01L 21/336

(52) U.S. Cl. 438/302; 257/E21.409

(57) ABSTRACT

A method for fabricating a semiconductor device, comprising the steps of: providing a semiconductor substrate including a core device region and an input/output device region, each of which is formed with a gate dielectric layer and a gate on the gate dielectric layer; performing a first ion implantation in the core device region and the input/output device region of the semiconductor substrate with the gate as a mask; performing a rapid thermal annealing to form low-doped source/drain regions in the semiconductor substrate at both sides of the gate dielectric layers of the core device region and the input/output device region; forming spacers over the sidewalls of the gate dielectric layers and gates of the core device region and the input/output device region; and performing a third ion implantation in the core device region and the input/output device region of the semiconductor substrate with the gate and spacer as a mask to form a heavily doped source/drain region. The saturation current of the device can be adjusted and the reliability of the input/output device can be improved by this method.

### FIELD OF THE INVENTION

The present invention relates to the field of semiconductor technology, particularly to a method for fabricating a semiconductor device.

### BACKGROUND OF THE INVENTION

With rapid development of semiconductor manufacturing technologies, semiconductor chips have being developed towards higher density of devices and higher level of integration in order to achieve faster computing speed, larger amount of data storage, and more functions. In most semiconductor chips, peripheral circuits need to use high-voltage input/output devices, while core devices, such as various memory devices, need to operate at low voltage. For achieving the optimization of the device performance, the channel length of the core device is shortened, which results in a short channel region and a short channel effect. To avoid the short channel effect, generally, a low doped source/drain (LDD) structure is used.

As the reduction of the channel length of the core device, generally, a semiconductor substrate and a source/drain region doped with higher concentration are used so that a high electric field is generated at the depletion region of the source/drain, thus the required drive current is obtained and the short channel effect is suppressed. When the high-voltage input/output device operates in saturation current state, charges in inversion layer are accelerated by the transverse electric field in the channel surface and are ionized by the collision with the crystal lattice, generating a lot of hot carriers (electron-hole pair). For NMOS devices, the generated hot carriers are injected into a gate dielectric layer under the surface gate-drain electric field to form hot-carrier injection (HCI), thus the operation characteristic and reliability of the device may be severely impacted. Meanwhile, a lot of hot carriers generated by the ionization through the collision may also cause a leakage current of the substrate to increase. The leakage current can be inhibited by raising the barrier through using multiple ion implantations to adjust and control the concentration of the doped ion.

To enhance the performance of the short channel region of the core device, rapid thermal annealing process is used in the low-doped source/drain region to activate the doped ions so as to avoid the diffusion and drift of the doped ions. A method for fabricating a device is disclosed in the U.S. Pat. No. 6,121,091, wherein the implanted ions are activated by rapid thermal annealing process. Its concrete process is shown in FIGS. 1-6.

Firstly, with reference to FIG. 1, a semiconductor substrate 1, which is divided into core device region 30 and input/output device region 40, is provided. On the core device region 30 and the input/output device region 40 of the semiconductor substrate 1, gate dielectric layer 2 which is silicon oxide and gate 3 which is polysilicon are formed in sequence.

With reference to FIG. 2, a photoresist layer 4 is formed so as to fully cover the input/output device region 40, and then a first ion implantation is performed on the core device region 30 with gate 3 as a mask to form an inactivated low-doped source/drain region 5a. The ions for the first ion implantation process are, for example, phosphorus ions, arsenic ions or the like. Subsequently, with reference to FIG. 3, a first rapid thermal annealing process is performed on the core device region 30 to form a low-doped source/drain region 5b, and the photoresist layer 4 fully covering the input/output device region 40 is removed.

After that, with reference to FIG. 4, a photoresist layer 6 is formed so as to fully cover the core device region 30, and then a second ion implantation is performed on the core device region 30 with gate 3 as a mask to form an inactivated low-doped source/drain region 7a. Like the first ion implantation process, the ions for the second ion implantation process are, for example, phosphorus ions, arsenic ions or the like. With reference to FIG. 5, the photoresist layer 6 is removed, and a spacer 8 made of silicon oxide is formed on the sidewalls of the gate dielectric layer 2 and gate 3 in the core device region 30 and that in the input/output device region 40. During the process of forming the spacer 8, the inactivated low-doped source/drain region 7a in the input/output device region 40 is formed into the activated low-doped source/drain region 7b.

Finally, with reference to FIG. 6, a third ion implantation is performed in the input/output device region 40 and the core device region 30 of the semiconductor substrate with the gate 3 and spacer 8 as a mask to form a heavily doped source/drain region 9. Using the fabricating method of the semiconductor device described above, the core device region and input/output device region of memory can be formed.

However, in the above method for fabricating a semiconductor device, only one ion implantation is performed to the low-doped source/drain region, thus it is difficult to inhibit the short channel effect due to the increasing reduction of the size of the device; meanwhile, no annealing process is performed to the low-doped source/drain region in the input/output device to completely activate and diffuse the impurity after the ion implantation, thus causing a strong electric field to be formed under the gate dielectric layer by the low-doped source region at the drain, resulting in a high degradation of the life of the input/output device.

### SUMMARY OF THE INVENTION

The object of the present invention is to suppress the short channel effect and enhance the reliability of the input/output device. In the present invention, a method for fabricating a semiconductor device is provided to improve the reliability of the input/output device and inhibit the leakage current of the substrate caused by the ionization through the collision while adjusting the saturation current of the device.

To solve the above problem, the present invention provides a method for fabricating a semiconductor device, comprising the steps of: providing a semiconductor substrate including a core device region and an input/output device region, each of which is formed with a gate dielectric layer and a gate on the gate dielectric layer;

performing a first ion implantation in the core device region and the input/output device region of the semiconductor substrate with the gate as a mask;

performing a rapid thermal annealing to form a low-doped source/drain region in the semiconductor substrate at both sides of the gate dielectric layers of the core device region and the input/output device region;

forming spacers on the sidewalls of the gate dielectric layers and gates of the core device region and the input/output device region; and

performing a third ion implantation in the core device region and the input/output device region of the semiconductor substrate with the gate and spacer as a mask to form heavily doped source/drain regions.

Preferably, after the first ion implantation and before the rapid thermal annealing process, the method further comprises a step of performing a second ion implantation in the core device region and the input/output device region of the semiconductor substrate with the gate as a mask.

Alternatively, before the first ion implantation, the method comprises a step of performing a second ion implantation in the core device region and the input/output device region of the semiconductor substrate with the gate as a mask.

Comparing to the prior art, the present invention has the following advantages:

1. By performing the rapid thermal annealing process after performing the ion implantation for the core device region and the input/output device region to activate the implanted ions, and by using the temperature condition of the rapid thermal annealing, the TED(transient enhanced diffusion) is avoided to reduce the peak value and the location of the transverse electric field in the device surface channel, the substrate leakage current and the current flowed from the gate dielectric layer are significantly reduced, hence the reliability of the device is improved.

2. By performing the ion implantation in the source/drain region twice, in which the type of the ions for the first ion implantation is same as that of the ions heavily implanted in the source/drain region, and the type of the ions for the second ion implantation is same as that of the ions implanted in the semiconductor substrate, and by adopting the multi-angle implantation to use the rotating ion implantation in the second ion implantation and optimize the implantation condition for the low doped source/drain in the first ion implantation, the short channel effect caused by the diffusion from the source/drain region to the channel can be effectively inhibited, and thus the device performance after the increasing reduction of the device size can be effectively improved without increasing the complexity of the process and the thermal budget and without affecting the performance of the core device.

### BRIEF DESCRIPTION OF THE DRAWINGS

FIGS. 1-6 are schematic diagrams showing a device structure fabricated by the prior art;

FIGS. 7-11 are schematic diagrams showing a device structure fabricated by the method for fabricating a semiconductor device according to the present invention;

FIG. 12 is a process flow chart of Embodiment 1 of the present invention;

FIG. 13 is a process flow chart of Embodiment 2 of the present invention; and

FIG. 14 is a process flow chart of Embodiment 3 of the present invention.

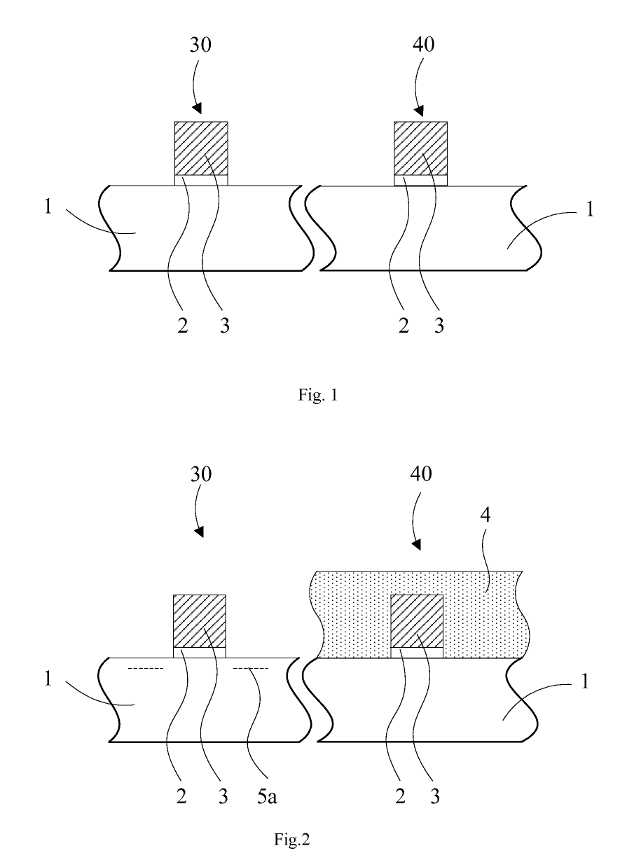

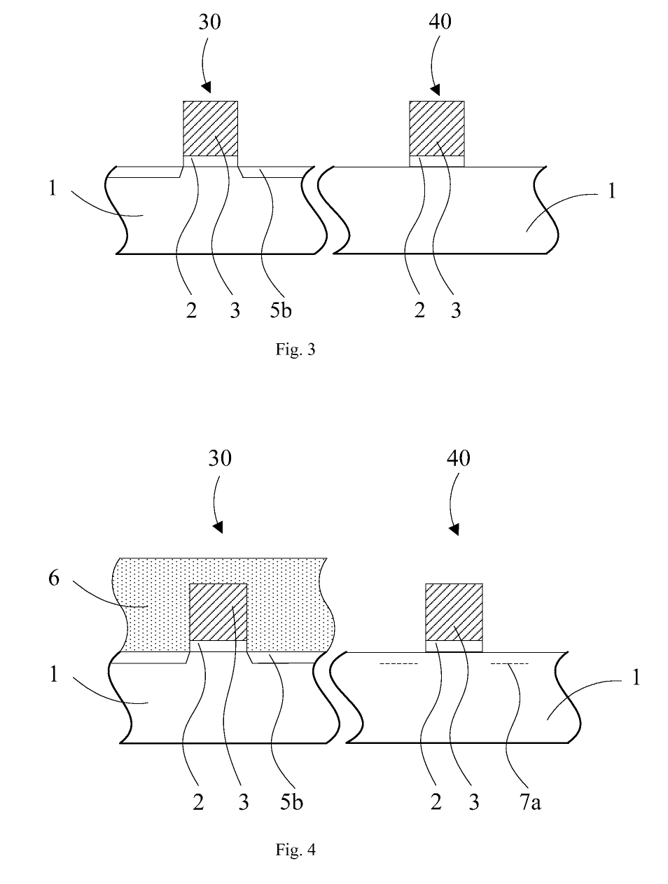

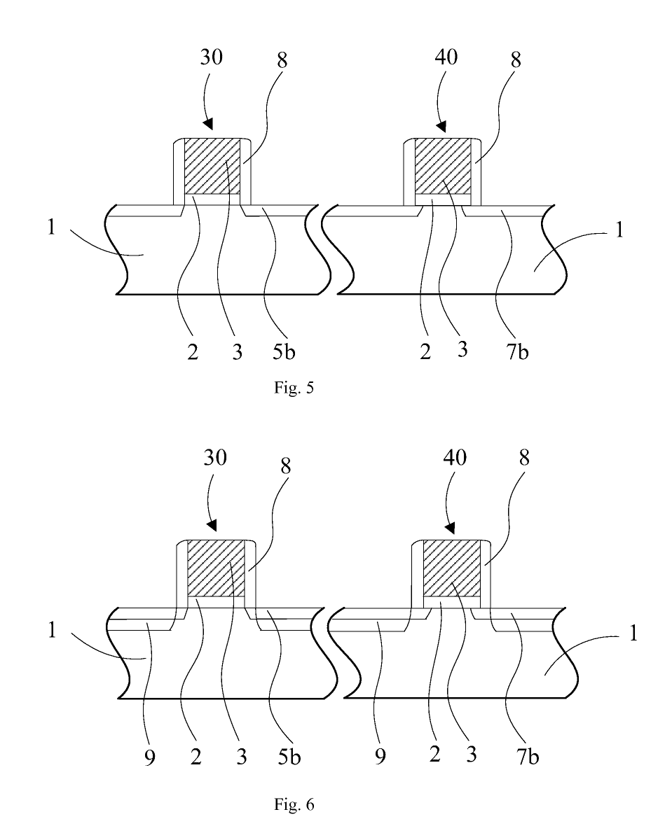

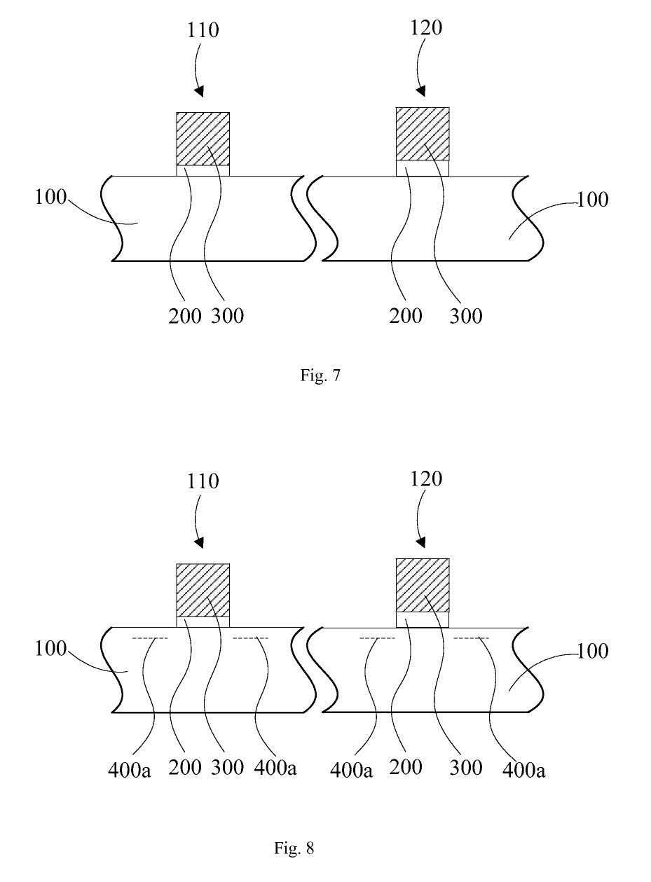

### DETAILED DESCRIPTION OF THE EMBODIMENTS

The essence of the present invention is that after an ion implantation is performed in a core device region and an input/output device region of a semiconductor substrate, a rapid thermal annealing is performed for these regions so as to improve the reliability of the formed input/output device of the semiconductor device.

Embodiments of the invention will be explained in detail below with reference to the drawings in order to the above objects, features and advantages of the invention can be more apparent.

### Embodiment 1

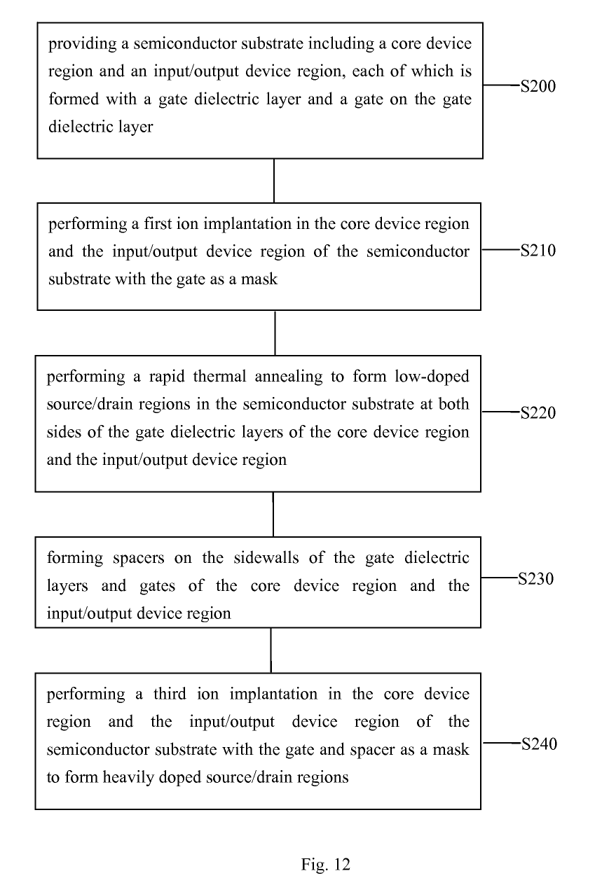

The present invention provides a method for fabricating a semiconductor device, comprising the steps of: as shown in FIG. 12, providing a semiconductor substrate including a core device region and an input/output device region, each of which is formed with a gate dielectric layer and a gate on the gate dielectric layer (S200); performing a first ion implantation in the core device region and the input/output device region of the semiconductor substrate with the gate as a mask (S210); performing a rapid thermal annealing to form low-doped source/drain regions in the semiconductor substrate at both sides of the gate dielectric layers of the core device region and the input/output device region (S220); forming spacers on the sidewalls of the gate dielectric layers and gates of the core device region and the input/output device region (S230); and performing a third ion implantation in the core device region and the input/output device region of the semiconductor substrate with the gate and spacer as a mask to form heavily doped source/drain regions (S240).

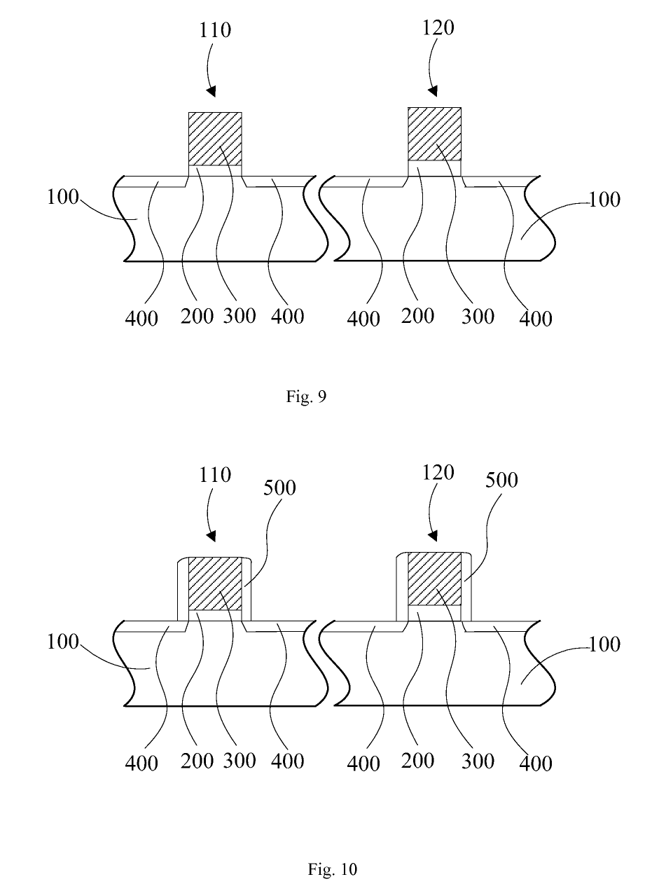

As shown in FIG. 7, a semiconductor substrate 100 including a core device region 110 and an input/output device region 120, each of which is formed with a gate dielectric layer 200 and a gate 300, is provided. The gate dielectric layer 200 can be silicon oxide, hafnium oxide, aluminum oxide, high-k dielectric material, silicon oxynitride or the like, and most preferably, is silicon oxide.

The gate dielectric layer 200 can be formed by a conventional multi-step thermal-oxide process well known to those skilled in the art. In general, the thickness of the gate dielectric layer 200 of the input/output device region 120 is larger than that in the core device region, thus after the gate dielectric layers 200 are formed on the semiconductor substrate, the thickness of the gate dielectric layer of the core device region is thinned by the selective etch process. The thickness of the gate dielectric layer 200 of the input/output device region 120 in this embodiment is 30-60 angstrom (Å).

The gate 300 is a polysilicon layer or polysilicide. It can be formed by a conventional process well known to those skilled in the art, and more preferably, by CVD method, for example, low-pressure plasma chemical vapor deposition or plasma enhanced chemical vapor deposition process.

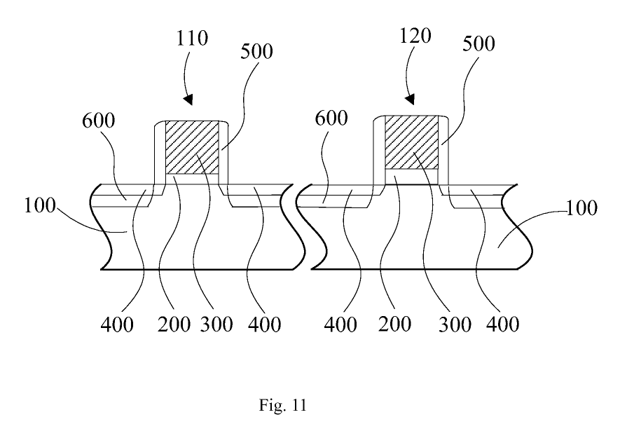

As shown in FIG. 8, with the gate 300 as a mask, a first ion implantation is performed in the core device region 100 and the input/output device region 120 of the semiconductor substrate 100, in which inactivated low-doped source/drain regions 400a are formed. The ions for the first ion implantation process are phosphorous (P) ions, arsenic (As) ions or the like, for example.

The process condition of the first ion implantation for P or As are as follows: the energy of ion implantation is 2-35 KeV and the dose of ion implantation is 5E12-2E15/cm², which are within a wider range so as to be optimized together with the energy and dose of a second ion implantation, thus obtaining the required drive current and device performance. In this embodiment, it is preferred that the energy of ion implantation is 5-20 KeV, and more preferably, is 10-14 KeV.

Further, when the ions for the first ion implantation are As ions, the energy of the ion implantation preferably is 2-35 KeV, and when the implanted ions are P ions, the energy of the ion implantation preferably is 8-17 KeV.

The energies of ion implantations used in the embodiments of the present invention are 8 KeV, 10 KeV, 12 KeV, 14 KeV, 18 KeV, 24 KeV and 30 KeV respectively, and the doses of ion implantations used in the embodiments of the invention are 8E13/cm², LE14/cm², 5E14/cm², 1E15/cm², etc, respectively.

Subsequently, as shown in FIG. 9, a rapid thermal annealing is performed to form low-doped source/drain regions 400 in the semiconductor substrate 100 at both sides of the gate dielectric layers 200 of the core device region 110 and the input/output device region 120.

The process condition of the rapid thermal annealing in the embodiments are as follows: it is in an atmosphere of inert gases such as nitrogen gas, argon gas, etc; the annealing temperature is 900-950° C., the annealing time is 5-120s, preferably is 10-60s, and more preferably is 10-30s.

After that, as shown in FIG. 10, spacers 500 are formed on the sidewalls of the gate dielectric layers 200 and gates 300 of the core device region 110 and the input/output device region 120. The spacer 500 can be formed by a conventional process well known to those skilled in the art, and more preferably, by CVD method. The material of the spacer 500 can be silicon oxide, silicon nitride, or the like. The thickness of the spacer 500 is 200-800 Å.

Finally, as shown in FIG. 11, a third ion implantation is performed in the core device region 110 and the input/output device region 120 of the semiconductor substrate 100 with the gates 300 and spacers 500 as a mask to form heavily doped source/drain regions 600. The ions for the third ion implantation are P ions, As ions or the like. The process conditions of the third ion implantation are as follows: the energy of ion implantation is 8-50 KeV and the dose of ion implantation is 1.5E14-6E15/cm². Using the above method for fabricating the semiconductor device, the core device region and the input/output device region of the memory can be formed.

According to the above method of the invention, after the first ion implantation is performed in the core device region and the input/output device region of the semiconductor substrate, rapid thermal annealing process is performed to the core device region and the input/output device region simultaneously, which can decrease the maximum electric field Emax of the input/output device and deepen its depth in the semiconductor substrate, resulting in the reduction of the substrate drain current, and consequently, the hot carrier performance of the input/output device is improved. Meanwhile, as the lateral diffusion ability of the implanted ion is enhanced, the drive current of the input/output device is increased by 4%.

By improving the implantation energy and adjusting the implantation depth of the implanted ions in the first ion implantation according to the invention, it is found that substrate leakage current of the input/output device decreases as the energy of ion implantation increases. As the energy of the first ion implantation is increased from 10 KeV to 14 KeV in the embodiment, the hot-carrier-injection effect of the device is improved by 20%. In addition, the drive current is increased by about 6% without any overload operation.

### Embodiment 2

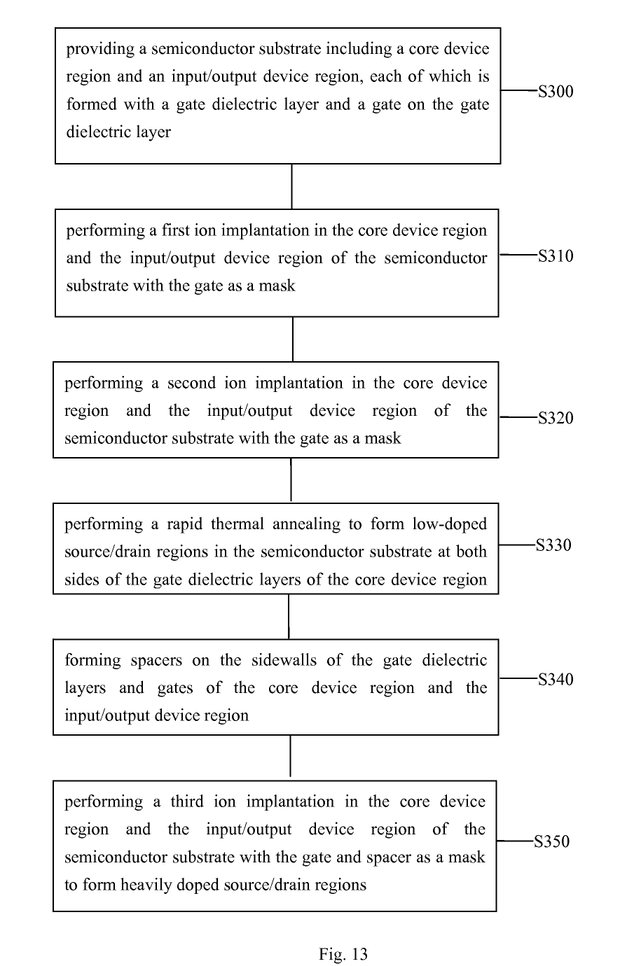

The present invention also provides a method for fabricating a semiconductor device, comprising the steps of: as shown in FIG. 13, providing a semiconductor substrate including a core device region and an input/output device region, each of which is formed with a gate dielectric layer and a gate on the gate dielectric layer (S300); performing a first ion implantation in the core device region and the input/output device region of the semiconductor substrate with the gate as a mask (S310); performing a second ion implantation in the core device region and the input/output device region of the semiconductor substrate with the gate as a mask (S320); performing a rapid thermal annealing to form low-doped source/drain regions in the semiconductor substrate at both sides of the gate dielectric layers of the core device region and the input/output device region (S330); forming spacers on the sidewalls of the gate dielectric layers and gates of the core device region and the input/output device region (S340); and performing a third ion implantation in the core device region and the input/output device region of the semiconductor substrate with the gate and spacer as a mask to form heavily doped source/drain regions (S350).

In this embodiment, the steps S300, S310, S330 and S340 are similar to that in Embodiment 1. This embodiment only describes that the process and its condition for performing the second ion implantation in the core device region and the input/output device region of the semiconductor substrate (S320). After rapid thermal annealing, the doped region formed by the second ion implantation can surround the low-doped source/drain region formed by the first ion implantation.

The ions for the second ion implantation process are boron (B) ions, indium (In) ions, etc., for example. The process condition of the second ion implantation is as follows: the energy of ion implantation is 3-150 KeV and the dose of ion implantation is 1E13-9E13/cm². Further, when the ions for the second ion implantation are B ions, the energy of ion implantation is 3-20 KeV, and preferably is 5-15 KeV; when the ions for the second ion implantation are In ions, the energy of ion implantation is 100-150 KeV, and preferably is 130-145 KeV. In an embodiment of the present invention, phosphorus (P) ions are implanted with the energy of 10 KeV and the dose of 5E13/cm².

In the second ion implantation, the angle for ion implantation is 0-45°. The rotating implantation is performed with the selected angle. The shadow effect can be reduced and the symmetry impurity distribution can be obtained by adopting the rotating implantation where its ion implantation is optimized along with the low-doped source/drain ion implantation and its implantation energy ensures that the low-doped source/drain junction under the gate can be surrounded so as to the short channel effect caused by DIBL (drain induced barrier lowing) is effectively inhibited.

With the process of this embodiment in which after the first ion implantation the second ion implantation is performed for the core device region and the input/output device region and then the rapid thermal annealing is performed so as to activate the implanted ions and to avoid the TED with the temperature condition of the rapid thermal annealing, the abruptness of distribution of the doping ions in low-doped source/drain region formed by the second ion implantation and the rapid thermal annealing can be reduced so that the peak value of the transverse electric field in surface channel near the source/drain region is reduced and separated from the current path, and consequently, the injection of hot carriers into the semiconductor substrate/gate dielectric layer interface can be effectively reduced and the reliability of the input/output device can be improved. Moreover, with the process described in this embodiment, the reliability of the input/output device can be improved without increasing the complexity of the process and the thermal budget and without affecting the performance of the core device.

### Embodiment 3

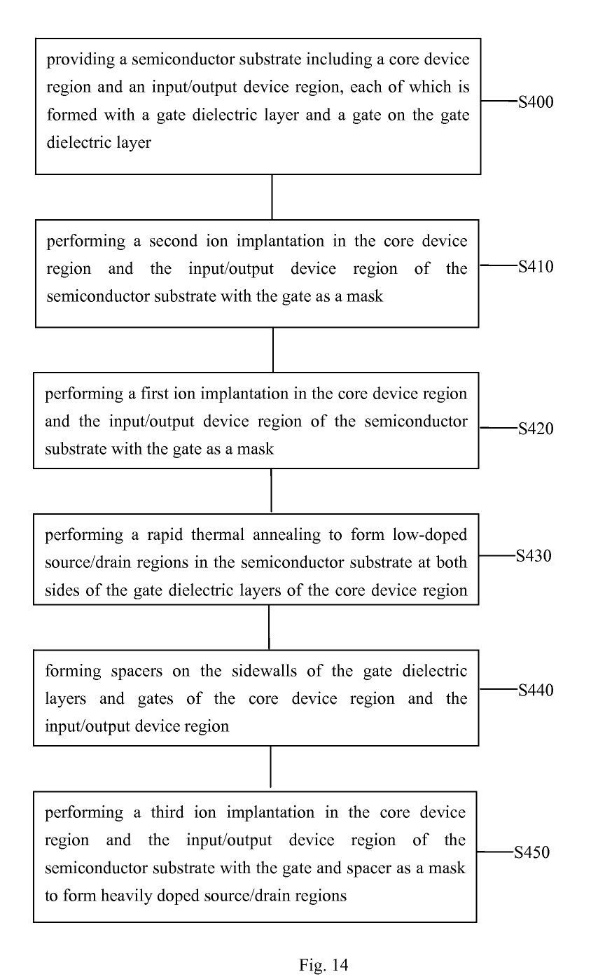

The present invention also provides a method for fabricating a semiconductor device, comprising the steps of: as shown in FIG. 14, providing a semiconductor substrate including a core device region and an input/output device region, each of which is formed with a gate dielectric layer and a gate on the gate dielectric layer (S400); performing a second ion implantation in the core device region and the input/output device region of the semiconductor substrate with the gate as a mask (S410); performing a first ion implantation in the core device region and the input/output device region of the semiconductor substrate with the gate as a mask (S420); performing a rapid thermal annealing to form low-doped source/drain regions in the semiconductor substrate at both sides of the gate dielectric layers of the core device region and the input/output device region (S430); forming spacers on the sidewalls of the gate dielectric layers and gates of the core device region and the input/output device region (S440); and performing a third ion implantation in the core device region and the input/output device region of the semiconductor substrate with the gate and spacer as a mask to form heavily doped source/drain regions (S450).

The order of the first ion implantation and the second ion implantation in Embodiment 2 is reversed in this embodiment. That is, the second ion implantation is first performed with the ions of B or In, the energy of 3-150 KeV, the dose of 1E13-9E13/cm² and the angle of 0-45°, the details of which can be referred to the above description in Embodiment 2; then, the first ion implantation is performed to form inactivated low-doped source/drain regions; and thereafter, the rapid thermal annealing is performed. Although the second ion implantation process is performed before the first ion implantation in this embodiment, after annealing, the doped region formed by the second ion implantation also can surround the inactivated low-doped source/drain region formed by the first ion implantation.

With the above process, the injection of hot carriers into the semiconductor substrate/gate dielectric layer interface also can be effectively reduced and the reliability of the input/output device also can be improved. Moreover, the reliability of the input/output device can be improved without increasing the complexity of the process and the thermal budget and without affecting the performance of the core device.

The above description is only the preferred embodiment of the present invention rather that limiting of the invention in any form. While the present invention has been disclosed by way of the preferred embodiments as above, it is not intended to limit the present invention. It is obvious for those skilled in the art that various variations and modifications can be made to the embodiments without departing from the scope of the present invention. Thus, it is intended that all such variations and modifications shall fall within the scope of the present invention as solely defined in the claims thereof.

What is claimed is:

1. A method for fabricating a semiconductor device, comprising the steps of:
providing a semiconductor substrate including a core device region and an input/output device region, each of which is formed with a gate dielectric layer and a gate on the gate dielectric layer;
performing a first ion implantation in the core device region and the input/output device region of the semiconductor substrate with the gate as a mask;
performing a rapid thermal annealing to form a low-doped source/drain region in the semiconductor substrate at both sides of the gate dielectric layers of the core device region and the input/output device region;
forming spacers on the sidewalls of the gate dielectric layers and gates of the core device region and the input/output device region; and
performing a third ion implantation in the core device region and the input/output device region of the semiconductor substrate with the gate and spacer as a mask to form heavily doped source/drain regions.

2. The method for fabricating a semiconductor device according to claim 1, further comprising a step of performing a second ion implantation in the core device region and the input/output device region of the semiconductor substrate with the gate as a mask after the first ion implantation and before the rapid thermal annealing process.

3. The method for fabricating a semiconductor device according to claim 1, further comprising a step of performing a second ion implantation in the core device region and the input/output device region of the semiconductor substrate with the gate as a mask before the first ion implantation.

4. The method for fabricating a semiconductor device according to claim 1, wherein the annealing temperature of the rapid thermal annealing is 900-950° C.

5. The method for fabricating a semiconductor device according to claim 1, wherein the annealing time of the rapid thermal annealing is 5-120 seconds.

6. The method for fabricating a semiconductor device according to claim 5, wherein the annealing time of the rapid thermal annealing is 10-30 seconds.

7. The method for fabricating a semiconductor device according to claim 1, wherein the ions for the first ion implantation are P or As ions.

8. The method for fabricating a semiconductor device according to claim 1, wherein the condition of the first ion implantation process includes: the energy of the ion implantation of 235 KeV and the dose of the ion implantation of 5E12-2E15/cm².

9. The method for fabricating a semiconductor device according to claim 2, wherein the ions for the second ion implantation are B or In ions.

10. The method for fabricating a semiconductor device according to claim 2, wherein the condition of the second ion implantation process includes: the energy of the ion implantation of 3-150 KeV and the dose of the ion implantation of 1E13-9E13/cm².

11. The method for fabricating a semiconductor device according to claim 2, wherein the implantation angle in the second ion implantation is 0-45°.

12. The method for fabricating a semiconductor device according to claim 1, wherein the ions for the third ion implantation are P or As ions, the energy of the ion implantation is 8-50 KeV and the dose of the ion implantation is 1E14-7E15/cm².

13. The method for fabricating a semiconductor device according to claim 1, wherein the gate is made of polysilicon or polysilicide.

14. The method for fabricating a semiconductor device according to claim 1, wherein the gate dielectric layer is made of silicon oxide or silicon oxynitride.

15. The method for fabricating a semiconductor device according to claim 1, wherein the spacer is made of silicon oxide or silicon nitride or silicon oxynitride.

16. The method for fabricating a semiconductor device according to claim 3, wherein the ions for the second ion implantation are B or In ions.

17. The method for fabricating a semiconductor device according to claim 3, wherein the condition of the second ion implantation process includes: the energy of the ion implantation of 3-150 KeV and the dose of the ion implantation of 1E13-9E13/cm².

18. The method for fabricating a semiconductor device according to claim 3, wherein the implantation angle in the second ion implantation is 0-45°.
